(19) United States
(12) Patent Application Publication
(10) Pub. No.: US 2026/0287623 A1
(43) Pub. Date: Sep. 24, 2026

(54) CURRENT SENSOR

(71) Applicant: Alps Alpine Co., Ltd., Tokyo (JP)

(72) Inventors: Manabu TAMURA, Miyagi-ken (JP); Masato NAKAMURA, Miyagi-ken (JP)

(21) Appl. No.: 19/685,681

(22) Filed: May 22, 2026

Related U.S. Application Data
(63) Continuation of application No. PCT/JP2024/036008, filed on Oct. 8, 2024.

(30) Foreign Application Priority Data
Dec. 5, 2023 (JP) 2023-205370

(51) Int. Cl. G01R 15/20; G01R 19/00

(52) U.S. Cl. CPC G01R 15/205; G01R 19/0092

(57) ABSTRACT

A current sensor that has high measurement precision and is suitable for profile reduction and downsizing is equipped with a magnetic sensor that incorporates a magnetic device and with a bus bar and a magnetic shield; the current sensor has a cancel member composed of a magnetic body. The cancel member is placed at a position at which a residual magnetic field generated by the magnetic shield is attenuated by a residual magnetic field generated by the cancel member. As a result, it is possible to reduce offset error in a state in which no current flows in the bus bar without complicating calculations involved in magnetism detection.

### CLAIM OF PRIORITY

This application is a Continuation of International Application No. PCT/JP 2024/036008 filed on Oct. 8, 2024, which claims benefit of Japanese Patent Application No. 2023-205370 filed on Dec. 5, 2023. The entire contents of each application noted above are hereby incorporated by reference.

### BACKGROUND OF THE INVENTION

### 1. Field of the Invention

The present invention relates to a current sensor that measures a current under measurement that flows in a bus bar.

### 2. Description of the Related Art

A current sensor in recent years measures a current under measurement that flows in a device to control a power supply system in a vehicle or the like that has various devices. An example of this type of current sensor has a magnetic detection portion that senses a magnetic field generated from a bus bar and also has a magnetic shield that shields an external magnetic field, which would otherwise become a disturbance to the magnetic detection portion.

In Japanese Unexamined Patent Application Publication No. 2021-47147, a current sensor is disclosed that has shield portions that shield magnetism in a state in which no current flows in a bus bar, in order to reduce offset error included in a sensor output. The current sensor has a first shield portion and a second shield portion that respectively generate a first magnetic field and a second magnetic field, which is oriented in a direction opposite to the direction of the first magnetic field, in a state in which no current flows in the bus bar. The first shield portion and second shield portion are placed so that the first magnetic field and second magnetic field are cancelled out by each other on a detection surface.

In Japanese Unexamined Patent Application Publication No. 2023-54490, a magnetic sensor is disclosed that is aimed at solving the problem that magnetic sensor's detection precision is lowered due to hysteresis error caused by a residual magnetic flux, which is generated when a magnetic shield or like is magnetized by a detection magnetic flux, a disturbance magnetic flux, or the like. The magnetic sensor acquires a corrected physical quantity, in which hysteresis error caused by a residual magnetic flux has been corrected, according to a difference between a first output value from a first magnetic detection portion and a second output value from a second magnetic detection portion.

### SUMMARY OF THE INVENTION

In the current sensor described in Japanese Unexamined Patent Application Publication 2021-47147, the first shield portion and second shield portion are provided; offset error is reduced by adjusting the placement of these two shield portions. However, the current sensor is problematic in that profile reduction and downsizing are difficult because the current sensor has two shield portions.

The magnetic sensor described in Japanese Unexamined Patent Application Publication 2023-54490 is also problematic in that calculations involved in magnetism detection are complicated because hysteresis error, which is caused by a residual magnetic flux, is corrected according to a difference between output values from the two magnetic detection portions.

In view of this, the present invention provides a current sensor that has high measurement precision and is suitable for profile reduction and downsizing; the current sensor can reduce offset error in a state in which no current flows in bus bar without complicating calculations involved in magnetism detection.

The present invention has a structure below as a means for solving the problems described above.

A current sensor is equipped with a magnetic sensor that incorporates a magnetic device and with a bus bar and a magnetic shield; the current sensor has a cancel member composed of a magnetic body. The cancel member is placed at a position at which a residual magnetic field generated by the magnetic shield is attenuated by a residual magnetic field generated by the cancel member.

Since the residual magnetic field generated by the magnetic shield can be attenuated by the cancel member provided separately from the magnetic shield, the influence of the residual magnetic field in magnetic field measurement can be suppressed.

The cancel member may be formed integrally with the magnetic sensor.

When the cancel member and magnetic sensor are integrally formed with each other, positional deviation is less likely to occur between the cancel member and the magnetic device in the magnetic sensor. Therefore, when compared with a structure in which the cancel member and magnetic sensor are separate bodies, the current sensor achieves high measurement precision with a low risk of error caused by positional deviation.

The cancel member may be placed inside a package that forms the outside shape of the magnetic sensor.

The cancel member may be placed on a surface of the magnetic device, the surface facing the bus bar.

The magnetic sensor may have a frame on which to mount the magnetic device, and the cancel member may be placed on the rear surface of a surface of the frame, the magnetic device being mounted on the surface.

The cancel member may be placed on the outer circumferential surface of a package that forms the outside shape of the magnetic sensor.

In a package process for manufacturing the magnetic sensor, the cancel member can be easily formed at a portion as described above by plating, pasting, or the like. Therefore, the current sensor can be efficiently manufactured.

The magnetic device may be a magnetoresistance effect element.

According to the present invention, when the cancel member is provided, a residual magnetic field generated by the magnetic shield is attenuated, so the influence of hysteresis can be suppressed in a simple structure. When the cancel member is placed in the vicinity of the magnetic device, the influence of the residual magnetic field from the magnetic shield can be suppressed by the cancel member with a small size. Therefore, it possible to provide a current sensor that has high measurement precision and is suitable for profile reduction and downsizing and in which offset error caused by the hysteresis of the magnetic shield is reduced.

### BRIEF DESCRIPTION OF THE DRAWINGS

FIG. 1 is a perspective view schematically illustrating the structure of a current sensor in an embodiment of the present invention;

FIG. 2 is a sectional view schematically illustrating the structure of the current sensor in FIG. 1, as taken along line II-II;

FIG. 3 is a sectional view schematically illustrating the structure of a variation of the current sensor in FIG. 2;

FIG. 4 is a sectional view schematically illustrating the structure of a magnetic sensor in the current sensor in FIG. 3;

FIG. 5 is a sectional view schematically illustrating the structure of a variation of the magnetic sensor in FIG. 4;

FIG. 6 is a sectional view schematically illustrating the structure of another variation of the magnetic sensor in FIG. 4;

FIG. 7 is a sectional view schematically illustrating the structure of a variation of the current sensor in FIG. 3;

FIG. 8 is a sectional view schematically illustrating the structure of another variation of the current sensor in FIG. 3;

FIG. 9 is a perspective view illustrating members involved in main portions to explain the sizes of members included in a current sensor in an example;

FIG. 10 is a graph illustrating measurement results representing the influence of hysteresis on measurement for the current sensor in the example and a current sensor in a comparative example; and

FIG. 11 is a sectional view schematically illustrating the structure of a conventional current sensor.

### DESCRIPTION OF THE PREFERRED EMBODIMENTS

Embodiments of the present invention will be described below with reference to the attached drawings. Identical members are assigned identical reference characters in the drawings and descriptions will be appropriately omitted. A reference coordinate system is appropriately shown on the drawing to indicate the positional relationship of members. In the reference coordinate system, the extending direction of a bus bar is the X direction; the direction of the width dimension of the bus bar, the direction being orthogonal to the X direction, is the Y direction; and the lamination direction of the bus bar and a magnetic sensor, the lamination direction being orthogonal to the X direction and Y direction, is the Z direction. The Y direction is the direction of a sensitivity axis of the magnetic sensor. The X direction and Z direction are orthogonal to the sensitivity axis.

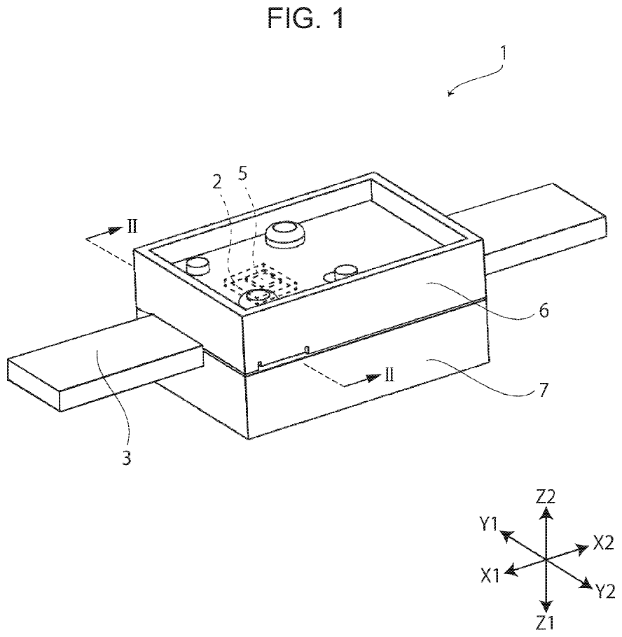

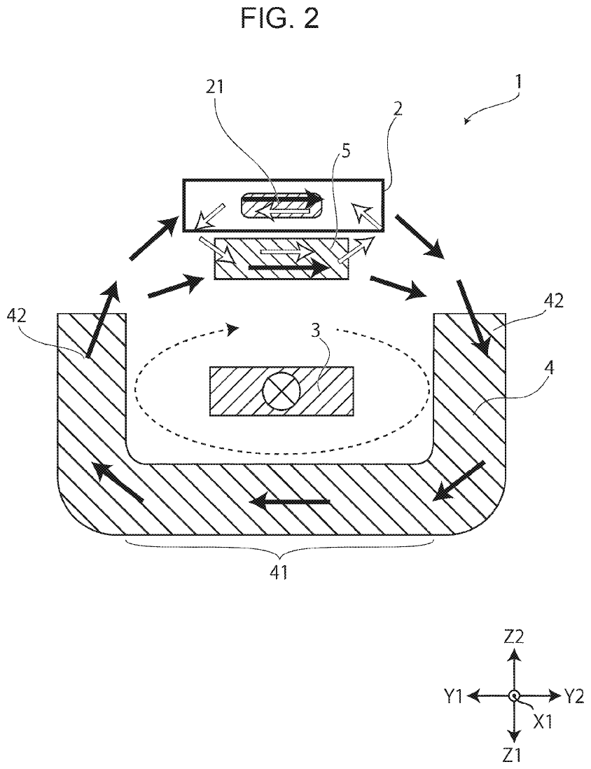

FIG. 1 is a perspective view schematically illustrating the structure of a current sensor 1 in an embodiment of the present invention. FIG. 2 is a sectional view schematically illustrating the structure of the current sensor 1 in FIG. 1, as taken along line II-II.

As illustrated in these drawings, the current sensor 1 is equipped with a magnetic sensor 2, a bus bar 3, and a magnetic shield 4, and has a cancel member 5 that attenuates a residual magnetic field from the magnetic shield 4. In FIG. 2 and other drawings referenced later, a first case 6 and a second case 7, which are illustrated in FIG. 1, are omitted for convenience of explanation.

The magnetic sensor 2, which incorporates a magnetic device 21, is mounted on a substrate (not illustrated). The magnetic device 21 is disposed so as to face the bus bar 3 in the Z direction to detect a magnetic field (magnetism) generated in the bus bar 3 by a current under measurement flowing in the bus bar 3. In the bus bar 3, the current flows in the X direction. When the magnetic field generated in the bus bar 3 by a current under measurement flowing in the bus bar 3 is viewed along the Z direction, the magnetic field is parallel to the Y direction at a position overlapping the bus bar 3. Therefore, when the sensing surface of the magnetism sensor 2 directly faces the bus bar 3 in the Z direction so that the sensitive axis of the magnetic sensor 2 (magnetic device 21) becomes parallel to the Y direction, magnetism generated by the bus bar 3 as an induced magnetic field can be precisely sensed by the magnetic device 21.

A magnetoresistance effect element, a hall element, or the like can be used as the magnetic device 21. In the structure described above, a magnetoresistive element is used as the magnetic device 21, as an example. If another type of magnetic device 21 is used, when the magnetic device 21 is to be placed, the orientation of the sensing surface and the like need to be appropriately changed.

The bus bar 3 is extended in the X direction among the X direction, Y direction, and Z direction, which are mutually orthogonal. The bus bar 3 is a conductor, formed like a plate, in which a current under measurement flows along the X direction. For example, the bus bar 3 is formed from a copper material, a brass material, an aluminum material, or the like. The normal direction of a surface of the bus bar 3, the surface facing the magnetic sensor 2, is the Z direction.

The bus bar 3 illustrated in FIG. 1 is held by being sandwiched between the first case 6 and the second case 7 from both sides in the Z direction. The current sensor 1 is structured so that the bus bar 3 is formed as a separate body and is then incorporated into the first case 6 and second case 7. However, the bus bar 3 may be molded integrally with the first case 6 or second case 7 by insert-molding or the like.

At least part of the magnetic shield 4, illustrated in FIG. 2, having a U-shape is insert-molded to the second case 7. The magnetic shield 4, which is a metallic plate-like body, can be formed by, for example, overlapping a plurality of plate-like bodies having the same shape (U-shape). When viewed along the X direction, the U-shape of the magnetic shield 4 has a bottom 41 and two side walls 42 extending from both ends of the bottom 41 toward the Z2 side.

The bottom 41 has a plate surface parallel to an XY plane. The bottom 41 is placed on the Z1 side in the Z direction with respect to the bus bar 3.

The side wall 42 has a plate surface parallel to an XZ plane. The side wall 42 extends from both ends of the bottom 41, one from each end, in the Y direction toward the Z2 side in the Z direction.

The magnetic shield 4 is placed so as to enclose both sides of the bus bar 3 in the Y direction and the Z1 side of the bus bar 3 in the Z direction. The magnetic sensor 2 is placed between the side walls 42 at both ends of the magnetic shield 4 when viewed along the Z axis.

Since the magnetic shield 4 is disposed, magnetic noise from the outside to the magnetic sensor 2 can be suppressed. However, the magnetic shield 4 is formed from a soft magnetic material, so the magnetic shield 4 may be magnetized by a magnetic field generated by a current under measurement flowing in the bus bar 3, the magnetic field being intended to be detected, a disturbance magnetic field intended to be shielded, or the like.

As described above, the magnetic shield 4 formed from a soft magnetic material may exhibit different magnetic states in a state in which no magnetic field is added, depending on the influence of previously added magnetism. This type of phenomenon, in which the magnetic state with no magnetic field added changes due to the influence of previously applied magnetization, is called hysteresis. Since the residual magnetic field from the magnetic shield 4 becomes noise when the magnetic device 21 detects magnetism, the residual magnetic field reduces the measurement precision of the current sensor 1.

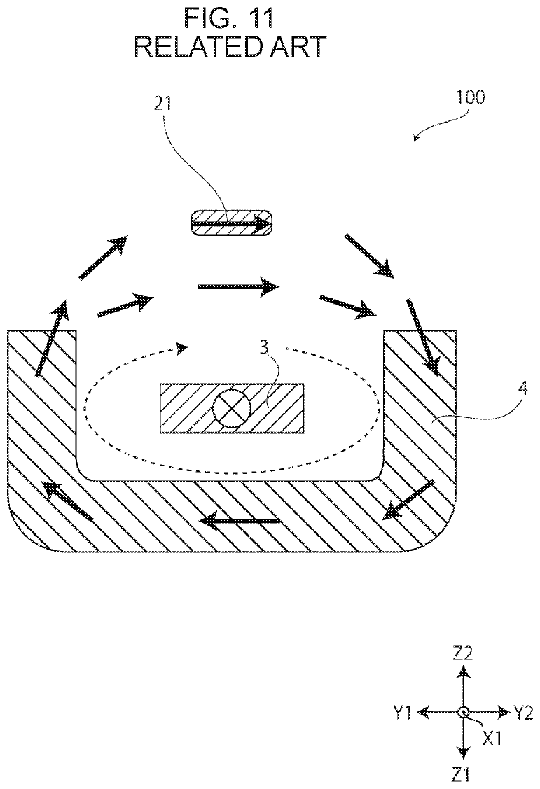

FIG. 11 is a sectional view schematically illustrating the structure of a current sensor 100 in related art. For example, when a current under measurement flows in the bus bar 3 as illustrated in FIG. 11, an induced magnetic field, such as one indicated by the dashed arrows in the drawing, is generated. When the magnetic shield 4 is affected by an induced magnetic field as illustrated in FIG. 11 and is thereby magnetized, a residual magnetic field, indicated by the solid arrows in the drawing, from the magnetic shield 4 is generated in the magnetic shield 4 even if a current is not flowing in the bus bar 3. This affects the magnetic device 21 in the magnetic sensor 2. Particularly, the magnetic shield 4 in a U-shape has larger hysteresis than a magnetic shield in a flat plate shape, which will be described later, in which case the current sensor 1 suffers a significant degradation in measurement precision.

In view of this, the current sensor 1 includes the cancel member 5 formed from a magnetic body separately from the magnetic shield 4 to reduce the influence of the residual magnetic field generated by the hysteresis of the magnetic shield 4. The cancel member 5 is placed at a position at which a residual magnetic field generated by the magnetic shield 4 is attenuated by the residual magnetic field generated by the cancel member 5. Specifically, the cancel member 5 is placed at a position at which a magnetic field, which is part of the residual magnetic field generated by the magnetic shield 4, that passes through the magnetic device 21 and a magnetic field, which is part of the residual magnetic field generated by the cancel member 5, that passes through the magnetic device 21 are oriented in directions in which these magnetic fields are cancelled out by each other.

In FIG. 2, the solid arrows indicate the residual magnetic field generated by the hysteresis of the magnetic shield 4, and the open arrows indicate the residual magnetic field generated by the cancel member 5. In other drawings as well, the residual magnetic field from the magnetic shield 4 is appropriately indicated by the sold arrows, and the residual magnetic field from the cancel member 5 is appropriately indicated by the open arrows.

When the cancel member 5 are placed between the magnetic device 21 and the bus bar 3 as illustrated in the drawing, the residual magnetic field generated by the cancel member 5 and the residual magnetic field generated by the magnetic shield 4 are in reverse directions in the vicinity of the magnetic device 21. As a result, it is possible to attenuate the residual magnetic field from the magnetic shield 4 by the cancel member 5 and thereby to suppress the influence of the hysteresis of the magnetic shield 4, the influence being given to the magnetic device 21. Therefore, the current sensor 1 with high measurement precision can be provided with the suppression of the influence of the hysteresis of the magnetic shield 4.

The position of the cancel member 5 illustrated in FIG. 2 is just an example. This is not a limitation on the position at which to place the cancel member 5 in the magnetic sensor 2. It suffices to place the cancel member 5 at a position at which the residual magnetic field generated by the magnetic shield 4 is attenuated on the magnetism sensing surface of the magnetic device 21 by the residual magnetic field from the cancel member 5. For example, the cancel member 5 may be placed opposite to the bus bar 3 with respect to the magnetic device 21.

In FIG. 2, only a magnetic field in the counterclockwise direction is indicated on the Z2 side of the cancel member 5 by the open arrow. However, a magnetic field in the clockwise direction is generated on the Z1 side of the cancel member 5. Therefore, even when the cancel member 5 is placed opposite to the bus bar 3 with respect to the magnetic device 21, since the residual magnetic field generated by the cancel member 5 is oriented toward the Y1 side in the vicinity of the magnetic device 21, the residual magnetic field generated by the magnetic shield 4 can be attenuated.

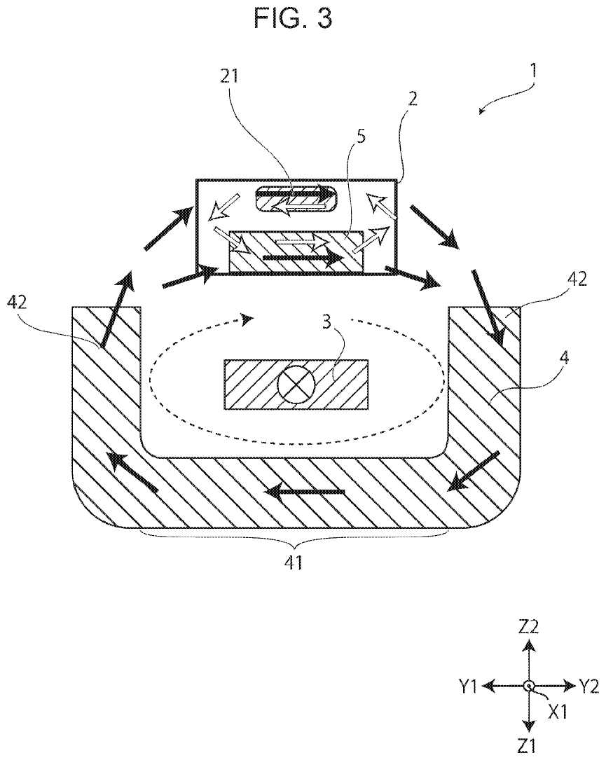

FIG. 3 is a sectional view schematically illustrating the structure of a variation of the current sensor 1 in FIG. 2. In the current sensor 1 illustrated in the drawing, the magnetic sensor 2 and cancel member 5 are formed integrally with each other. When the magnetic sensor 2 and cancel member 5 are integrally formed, positional deviation is less likely to occur between the cancel member 5 and the magnetic device 21 included in the magnetic sensor 2. Therefore, the influence of the residual magnetic field from the magnetic shield 4 can be precisely cancelled out, so the current sensor 1 with high measurement precision can be provided.

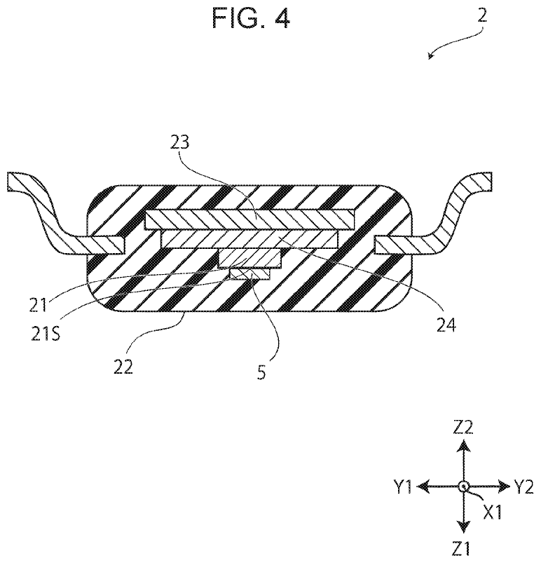

FIG. 4 is a sectional view schematically illustrating the structure of the magnetic sensor 2 in the current sensor 1 in FIG. 3. In the magnetic sensor 2 illustrated in the drawing, the cancel member 5 is placed inside a package 22 formed from a mold resin or the like, the package 22 forming the outside shape of the magnetic sensor 2. Specifically, the cancel member 5 is placed on a surface facing the bus bar 3 (see FIG. 3), the surface being part of a surface 21S of the magnetic device 21 disposed on an integrated circuit 24 on a frame 23 in the package 22.

When the cancel member 5 is placed inside the package 22 as described above, the distance between the cancel member 5 and the magnetic device 21 can be shortened. As a result, the influence of the residual magnetic field from the magnetic shield 4 can be efficiently suppressed by the residual magnetic field from the cancel member 5.

The cancel member 5 can be easily formed on the surface 21S of the magnetic device 21 in a process for forming the magnetic device 21. Methods of forming the cancel member 5 include plating, sputtering, pasting, and the like.

The current sensor 1 in this embodiment has the cancel member 5 used to cancel out the influence of the hysteresis of the magnetic shield 4. Thus, the cancel member 5 used to suppress the influence of the hysteresis of the magnetic shield 4 is placed in the vicinity of the magnetic device 21, as a component separate from the magnetic shield 4 that shields magnetism. Therefore, the cancel member 5 can be structured with a magnetic body smaller than the magnetic shield 4, so it is possible to achieve downsizing of the current sensor 1 and the suppression of the influence of hysteresis caused by residual magnetization of the magnetic shield 4.

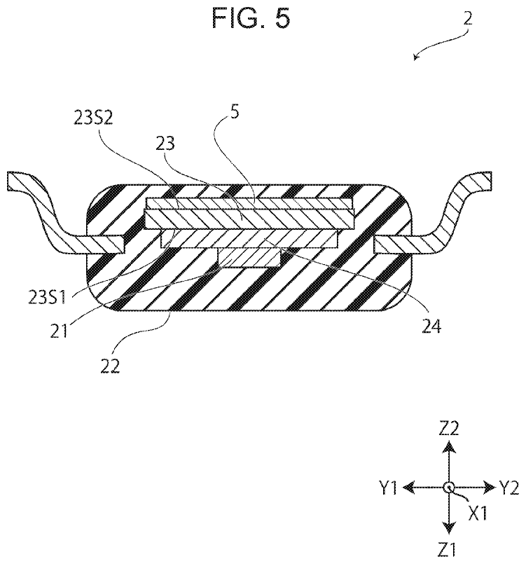

FIG. 5 is a sectional view schematically illustrating the structure of a variation of the magnetic sensor 2 in FIG. 4. In the magnetic sensor 2 illustrated in the drawing, the cancel member 5 is formed on a surface of the frame 23. Specifically, the magnetic sensor 2 has the frame 23 on which to mount the magnetic device 21 and integrated circuit 24; the cancel member 5 may be placed on a surface 23S2 on the rear side of a surface 23S1 of the frame 23 on the Z1 side, the magnetic device 21 being mounted on the surface 23S1. In a package process for manufacturing the magnetic sensor 2, the cancel member 5 can be easily formed on the surface of the frame 23 by plating, pasting, or the like. Therefore, the current sensor 1 can be efficiently manufactured.

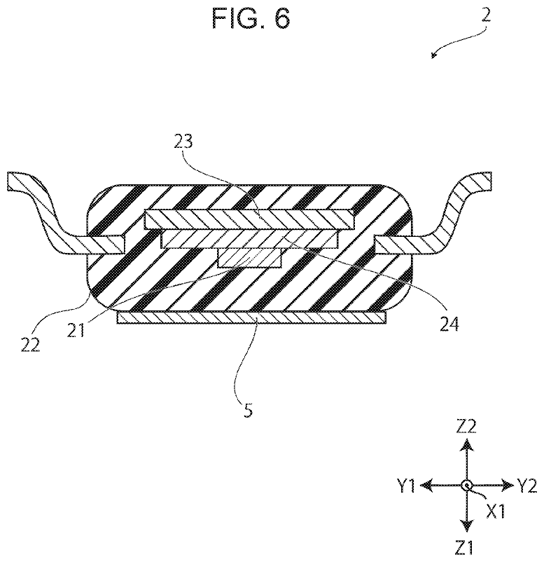

FIG. 6 is a sectional view schematically illustrating the structure of another variation of the magnetic sensor 2 in FIG. 4. In the magnetic sensor 2 illustrated in the drawing, the cancel member 5 is placed on the outer circumferential surface of the package 22. In a package process for manufacturing the magnetic sensor 2, the cancel member 5 can be easily formed on the outer circumferential surface of the package 22 by plating, pasting, or the like, as in aspects illustrated in FIGS. 4 and 5. As a result, the current sensor 1 having the cancel member 5 can be efficiently manufactured.

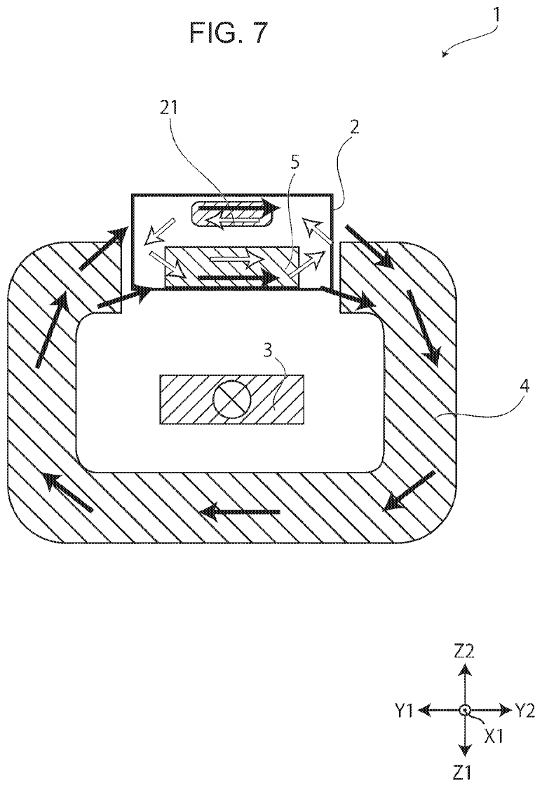

FIG. 7 is a sectional view schematically illustrating the structure of a variation of the current sensor 1 in FIG. 3. As illustrated in the drawing, the magnetic shield 4 of the current sensor 1 may be of a C-shape type (in a core shape), instead of a U-shape type. Even if the magnetic shield 4 of C-shape type is used, when the cancel member 5 is provided, it is possible to suppress the influence of the residual magnetic field from the magnetic shield 4 on the magnetic device 21 and to improve the measurement precision of the current sensor 1.

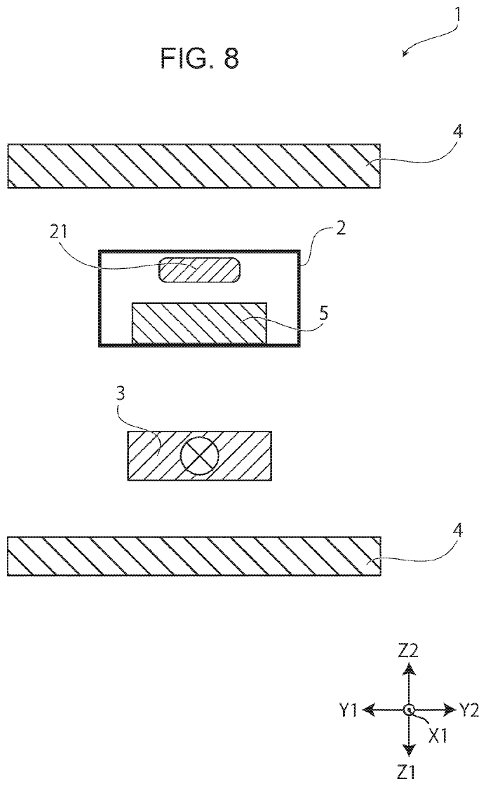

FIG. 8 is a sectional view schematically illustrating the structure of another variation of the current sensor 1 in FIG. 3. As illustrated in the drawing, the magnetic shield 4 of the current sensor 1 may be of a parallel flat plate type, instead of a U-shape type. Even if the magnetic shield 4 of parallel flat plate type is used, when the cancel member 5 is provided, the influence of the hysteresis of the magnetic shield 4 can be suppressed and the measurement precision of the current sensor 1 is thereby improved.

### EXAMPLES

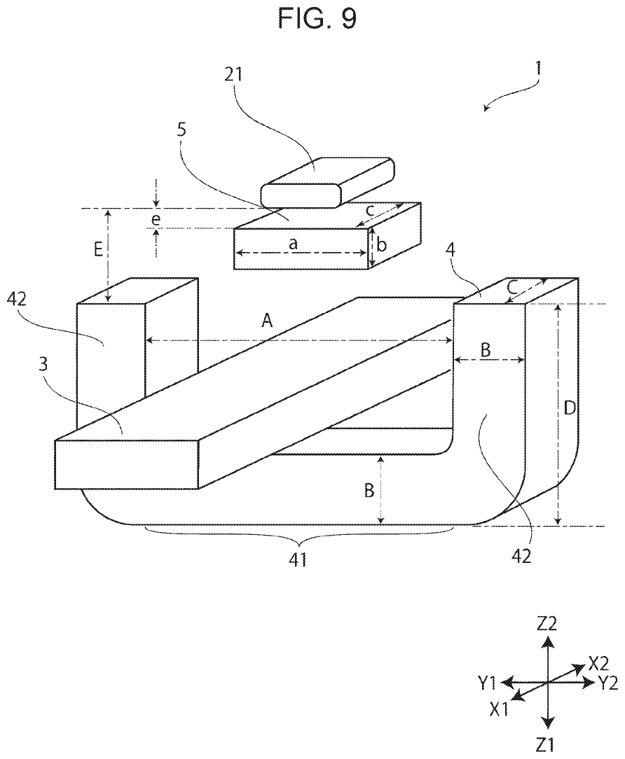

FIG. 9 is a perspective view illustrating members involved in main portions to explain the dimensions (sizes) of members included in the current sensor 1 in an example. FIG. 9 and other drawings are schematic drawings in which sizes have been adjusted for convenience of explanation; the dimensions of components included in the current sensor 1 do not match their actual sizes.

The sizes of individual portions in the current sensor 1 in the example will be indicated below.

The magnetic shield 4 used was such that a width A of the bottom 41 in the Y direction (a clearance between the two side walls 42 in the Y direction) is 10 mm; a thickness B of the bottom 41 and side wall 42 is 2 mm; a depth C of the bottom 41 and side wall 42 in the X direction is 6 mm; and a length D of the side walls 42 extending from both sides of the bottom 41 in the Z direction is 6 mm.

The cancel member 5 used was such that a width a in the Y direction is 1 mm, a thickness b in the Z direction is 0.03 mm, and a depth c in the X direction is 0.1 mm.

A clearance E between the magnetic shield 4 and the magnetic device 21 in the Z direction (a clearance between an end of the side wall 42 on the Z2 side and the detection surface of the magnetic device 21 on the Z1 side) was 0.5 mm. A clearance e between the cancel member 5 and the magnetic device 21 in the Z direction was 0.05 mm.

The current sensor 100 used in a comparative example differed from the current sensor 1 in the example in that the cancel member 5 is not provided, but had the same sizes of the width A, thickness B, depth C, and length D of the magnetic shield 4 as well as the same clearance E between the magnetic shield 4 and the magnetic device 21 in the Z direction as the current sensor 1.

For the current sensor 1 and current sensor 100 described above, a current under measurement to be entered into the bus bar 3 was sequentially changed step by step from 0 A to +450 A, from +450 A to 0 A, from 0 A to −450 A, and from −450 A to 0 A, after which outputs from the current sensor 1 were measured. The signs + and − prefixed to the current values indicate the directions of the current under measurement in the bus bar 3. That is, the current under measurement was increased and decreased in a range of 0 A to 450 A, and was then increased and decreased in a range of 0 A to 450 A but in the reversed direction.

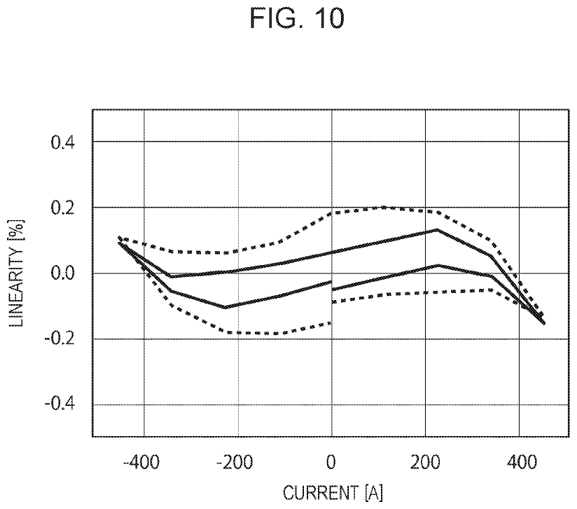

FIG. 10 is a graph that represents deviation of measured outputs from an approximate straight line as linearity (%), where the approximate straight line was obtained from all the measured values obtained and the measured outputs were compared with the approximate straight line. For example, when an output value obtained from measurement about a certain current under measurement is 101 and an output value based on calculation according to the approximate straight line obtained on the basis of all measured values is 100, the linearity is +1% (=(101−100)/100×100).

The graph in FIG. 10 indicates results in measurement of the influence of the hysteresis of the magnetic shield 4 for the current sensor 1 in the example illustrated in FIG. 3 and for the current sensor 100 in the comparative example illustrated in FIG. 11; the solid lines indicate measurement results in the example and the dashed lines indicate measurement results in the comparative example.

As illustrated in the graph in FIG. 10, when the cancel member 5 was placed in the magnetic sensor 2, the influence of the residual magnetic field due to the hysteresis of the magnetic shield could be suppressed and linearity in measurement for the current sensor 1 was improved.

The graph illustrated in FIG. 10 is discontinuous at a current of 0 A. This is because of the influence of hysteresis, by which a difference occurred between an initial evaluation value at 0 A and an evaluation result when the current was returned to 0 A after it had been changed.

In the current sensor 1 in the example, the cancel member 5 is placed in the vicinity of the magnetic device 21 to suppress the influence of the residual magnetic field by the cancel member 5 with a small size. Since linearity in measurement by the current sensor 1 is improved by the cancel member 5 with a small size in this way, this is advantageous in downsizing, profile reduction, and weight reduction of the current sensor 1.

According to the results for the current sensor 1 in the example, it can be said that linearity in measurement by the current sensor 1 is improved when the cancel member 5 is placed in the vicinity of the magnetic device 21 so that the clearance e between the cancel member 5 and the magnetic device 21 in the magnetic sensor 2 is 1/20 to 4/20 the clearance of E between the magnetic device 21 and the magnetic shield 4, 0.25 to 0.10 mm, and the cancel member 5 with a small size, is used, the width a being about 1/20 to 4/20 the width A of the bottom 41 of the magnetic shield 4, the thickness b being about 1/200 to 6/200 the thickness B of the magnetic shield 4, the depth c being about 1/120 to 4/120 the depth C of the magnetic shield 4.

The embodiments disclosed in this description are exemplary in all points. The present invention is not restricted to these embodiments. The scope of the present invention is not indicated by the description of only the embodiments described above but is indicated by the scope of the claims. It is intended that meanings equivalent to the scope of the claims and all modifications in the scope are included.

The present invention is useful as, for example, a current sensor that measures a current under measurement that flows in a device to control a power supply system in a vehicle or the like that has various devices.

What is claimed is:

1. A current sensor comprising:
a magnetic sensor;
a magnetic device incorporated in the magnetic sensor;
a bus bar;
a magnetic shield; and
a cancel member composed of a magnetic body; wherein
the cancel member is formed integrally with the magnetic sensor, is placed inside a package that forms an outside shape of the magnetic sensor, one cancel member being provided for one magnetic sensor, and is placed at a position at which a residual magnetic field generated by the magnetic shield is attenuated by a residual magnetic field generated by the cancel member.

2. A current sensor comprising:
a magnetic sensor;
a magnetic device incorporated in the magnetic sensor;
a bus bar;
a magnetic shield; and
a cancel member composed of a magnetic body; wherein
the cancel member is formed integrally with the magnetic sensor, is placed on an outer circumferential surface of a package that forms an outside shape of the magnetic sensor, one cancel member being provided for one magnetic sensor, and is placed at a position at which a residual magnetic field generated by the magnetic shield is attenuated by a residual magnetic field generated by the cancel member.

3. The current sensor according to claim 1, wherein the cancel member has a shape like a flat plate.

4. The current sensor according to claim 2, wherein the cancel member is placed on a surface of the package of the magnetic device, the surface facing the bus bar.

5. The current sensor according to claim 1, wherein:
the magnetic sensor has, in an interior of the package, a frame on which to mount the magnetic device; and
the cancel member is placed on a rear surface of the frame, the rear surface being opposite to a surface on which the magnetic device is mounted.

6. The current sensor according to claim 3, wherein a thickness of the cancel member is 1/200 to 6/200 a thickness of the magnetic shield.

7. The current sensor according to claim 1, wherein the magnetic device is a magnetoresistance effect element.
